(19) United States
(12) Patent Application Publication
(10) Pub. No.: US 2016/0020003 A1
(43) Pub. Date: Jan. 21, 2016

(54) OXIDE SUPERCONDUCTOR COMPOSITION, OXIDE SUPERCONDUCTOR WIRE, AND PRODUCTION METHOD FOR OXIDE SUPERCONDUCTOR WIRE

(71) Applicants: INTERNATIONAL SUPERCONDUCTIVITY TECHNOLOGY CENTER, Kawasaki-shi, Kanagawa (JP); SWCC SHOWA CABLE SYSTEMS CO., LTD., Minato-ku, Tokyo (JP)

(72) Inventors: Koichi NAKAOKA, Tokyo (JP); Masateru YOSHIZUMI, Kanagawa (JP); Teruo IZUMI, Tokyo (JP); Yuh SHIOHARA, Kanagawa (JP); Tatsunori NAKAMURA, Kanagawa (JP)

(21) Appl. No.: 14/771,230

(22) PCT Filed: Feb. 27, 2014
(86) PCT No.: PCT/JP2014/001042

§ 371 Date: Aug. 28, 2015

(30) Foreign Application Priority Data
Feb. 28, 2013 (JP) 2013-039810

(51) Int. Cl. H01B 12/00; H01B 13/00; H01B 12/06

(52) U.S. Cl. CPC H01B 12/00; H01B 12/06; H01B 13/00

(57) ABSTRACT

Provided is an oxide superconductor composition that makes it possible to increase film thickness, increase production speed, and decrease costs when producing a REBaCuO-type oxide superconductor wire (wherein RE is at least one element selected from the group consisting of Y, Nd, Sm, Gd, Dy, Eu, Er, Yb, Pr, and Ho). The oxide superconductor comprises, as essential components thereof, an RE salt of a carboxylic acid that serves as an RE component, that does not contain a ketone group, and that has 3-8 carbon atoms, barium trifluoroacetate that serves as a Ba component, one or more copper salts that serve as a Cu component and that are selected from the group consisting of copper salts of branched saturated aliphatic carboxylic acids having 6-16 carbon atoms and copper salts of alicyclic carboxylic acids having 6-16 carbon atoms, and an organic solvent that dissolves the aforementioned metal salt components.

### TECHNICAL FIELD

The present invention relates to an REBaCuO (where RE is at least one element selected from the group consisting of Y, Nd, Sm, Gd, Dy, Eu, Er, Yb, Pr and Ho)-based oxide superconductor composition, an oxide superconductive wire utilizing the oxide superconductor composition, and a manufacturing method of the oxide superconductive wire.

### BACKGROUND ART

Since the critical temperature (Tc) of oxide superconductors is higher than the liquid nitrogen temperature, use of oxide superconductors for superconductive magnets, superconductive cables, power apparatuses and other applications is expected, and various studies are extensively conducted.

To apply oxide superconductors to superconductive magnets, superconductive cables, power apparatuses and the like, it is necessary to manufacture a long wire having a high critical current density Jc and a high critical current value Ic. On the other hand, to obtain an oxide superconductor as a tape-shaped long wire, it is necessary to form an oxide superconductor on a tape-shaped metal substrate from the standpoint of strength and flexibility.

Oxide superconductors exhibit different superconductive characteristics depending on their crystal orientation, and therefore the in-plane crystal orientation is required to be improved. That is, when the crystal orientation of the superconductor is not aligned at the time of crystallization, a superconductive current does not smoothly flow, and consequently critical current density Jc and critical current value Ic (Ic=Jc×film thickness×width) are reduced. For this reason, it is necessary for the crystals to be epitaxially grown in accordance with the crystal orientation of the underlying intermediate layer, and it is necessary to achieve crystal growth excellent in orientation from the substrate toward the film surface.

In view of this, to improve critical current density Jc, the c-axis of the oxide superconductor crystal is aligned along a direction (film thickness direction) perpendicular to the substrate surface, and the-a axis (or b-axis) is in-plane aligned along a direction parallel to the substrate surface.

An MOD method (metal organic deposition process) is an example of the method of manufacturing an oxide superconductor thin film on a tape-shaped metal substrate (hereinafter referred to as “substrate”). In this method, a metal organic compound solution is applied on a substrate, and then the metal organic compound is subjected to thermal treatment (pre-baking treatment) at approximately 500° C. for example and is thermally decomposed. Then, the thermally decomposed product thus obtained (a precursor of the oxide superconductor) is further subjected to thermal treatment (main baking treatment) at a high temperature (approximately 800° C. for example) for crystallization, thereby manufacturing an oxide superconductor. This method requires only a simple manufacturing facility, and can easily handle a large area and a complicated shape in comparison with vapor phase methods (evaporation method, sputtering method, pulse laser evaporation method and the like) for manufacturing mainly in vacuum.

A known example of the MOD method is a TFA-MOD method (Metal Organic Deposition using Trifluoroacetates) that uses an organic acid salt containing fluorine as a raw material.

In the TFA-MOD method, a superconductor is produced by a reaction of water vapor with an amorphous precursor containing fluorine obtained after the pre-baking treatment of a coating film, and the decomposition rate of the fluoride can be controlled by the water vapor partial pressure during the thermal treatment. Thus, a superconductor film having excellent in-plane orientation can be produced by controlling the crystal growth rate of the superconductor. In addition, this method can achieve epitaxial growth of an RE-based (123) superconductor on a substrate at relatively low temperatures.

As described above, when a tape-shaped oxide superconductor is manufactured by the MOD method, it is indispensable for practical use to increase the film thickness for improving critical current value Ic. When the MOD method using a TFA salt as a starting material is used, the film thickness may be increased by improving the wettability of the material solution to the substrate. When the thickness of the coating film per application is increased, the amount of resulting HF and CO₂ gas as the decomposition products increases and the coating film scatters at the time of the pre-baking treatment, and as a result, it is difficult to manufacture a highly functional tape-shaped oxide superconductor thick film.

For this reason, normally, a thick film oxide superconductor is produced by repeating application of raw materials and the pre-baking treatment while limiting the thickness of the coating film per application so as to increase the thickness of the precursor of the oxide superconductor. However, in the above-mentioned conventional pre-baking treatment method, since the temperature rise rate during the pre-baking treatment that has an influence on the decomposition rate of metal organic acid salt is high, decomposition of metal organic acid salt such as TFA salt is insufficient, and consequently organic compound tends to remain in the precursor of the oxide superconductor film obtained by pre-baking. As a result, when the temperature rises in the subsequent crystallization thermal treatment, the remaining organic compound is abruptly decomposed, and crack and pore are caused in the film.

Such tendency is significant when an oxide superconductor precursor film having a multi-layer structure is formed by repeating application and pre-baking treatment so as to increase the film thickness. This makes it difficult to achieve epitaxial growth at the time when the oxide superconductor precursor film thus obtained is crystallized to obtain a superconductor film, and a superconductor thick film having excellent in-plane orientation cannot be easily obtained, whereby critical current density Jc characteristics are peaked. Further, critical current density Jc characteristics are significantly reduced when crack is caused.

In view of the above-mentioned problems, PTL 1, for example, discloses a method of reducing the remaining of organic chain such as fluoride in the oxide superconductor precursor film with use of a salt of a C₄₋₈ keto acid as an RE component. In this manner, an REBaCuO-based oxide superconductor film is uniformly formed with a high speed.

### CITATION LIST

### Patent Literature

### PTL 1

### Japanese Patent Application Laid-Open No. 2010-192142

### SUMMARY OF INVENTION

### Technical Problem

As a method for applying a metal organic compound solution to a substrate in the MOD method, a so-called dip-coating method is known in which a tape-shaped substrate on which an oxide intermediate layer is formed is dipped in a metal organic compound solution obtained by dissolving organic acid salt in organic solvent, and the substrate is lifted from the metal organic compound solution.

There is a demand of increasing the film thickness of the metal organic compound solution that adheres to the substrate at the time of dip coating for the purpose of increasing the thickness of the oxide superconductor. That is, there is a demand of manufacturing an oxide superconductive wire having a thick film oxide superconductor with a high speed by using an oxide superconductor composition having high wettability in comparison with the metal organic compound solution containing a salt of a C₄₋₈ keto acid as the RE component disclosed in PTL 1.

An object of the present invention is to provide an oxide superconductor composition, an oxide superconductive wire and a manufacturing method of the oxide superconductive wire which can achieve increase in film thickness and speed and reduction in cost at the time of manufacturing an oxide superconductor.

### Solution to Problem

An oxide superconductor composition of an aspect of the present invention is intended for forming an REBaCuO (where RE is at least one element selected from the group consisting of Y, Nd, Sm, Gd, Dy, Eu, Er, Yb, Pr and Ho)-based oxide superconductor, the oxide superconductor composition including, as essential components: an RE salt of a C₃₋₈ carboxylic acid that is free from ketone group and serves as an RE component; barium trifluoroacetate that serves as a Ba component; at least one copper salt that serves as a Cu component selected from the group consisting of copper salts of C₆₋₁₆ branched saturated aliphatic carboxylic acids and copper salts of C₆₋₁₆ alicyclic carboxylic acids; and an organic solvent that dissolves salts of the metals.

An oxide superconductive wire of an aspect of the present invention includes an REBaCuO (where RE is at least one element selected from the group consisting of Y, Nd, Sm, Gd, Dy, Eu, Er, Yb, Pr and Ho)-based oxide superconductor, the oxide superconductor including, as essential components: an RE salt of a C₃₋₈ carboxylic acid that is free from ketone group and serves as an RE component; barium trifluoroacetate that serves as a Ba component; at least one copper salt that serves as a Cu component selected from the group consisting of copper salts of C₆₋₁₆ branched saturated aliphatic carboxylic acids and copper salts of C₆₋₁₆ alicyclic carboxylic acids; and an organic solvent that dissolves salts of the metals.

A manufacturing method of an oxide superconductive wire of an aspect of the present invention includes: applying a solution of the oxide superconductor composition according to any one of claims 1 to 4 to a surface of a tape-shaped base material by lifting the base material from a container storing the solution; applying pre-baking treatment to the solution applied on the base material to form a precursor of an oxide superconductor on the surface of the base material; and forming an REBaCuO (where RE is at least one element selected from the group consisting of Y, Nd, Sm, Gd, Dy, Eu, Er, Yb, Pr and Ho)-based oxide superconductor on the surface of the base material by applying main baking treatment to the precursor to cause crystallization.

### Advantageous Effects of Invention

According to the present invention, it is possible to achieve increased film thickness, high speed and cost reduction in the manufacture of an oxide superconductor.

### BRIEF DESCRIPTION OF DRAWINGS

FIGS. 1A to 1E are schematic views illustrating a manufacturing method of a tape-shaped oxide superconductive wire having an REBaCuO-based superconductive layer with use of an MOD method.

### DESCRIPTION OF EMBODIMENTS

In the following, an embodiment of the present invention will be described in detail with reference to the accompanying drawings.

An REBaCuO (where RE is at least one element selected from the group consisting of Y, Nd, Sm, Gd, Dy, Eu, Er, Yb, Pr and Ho)-based oxide superconductor composition according to the embodiment of the present invention is a composition serving as a superconductor composed of a composite oxide of RE, Ba and Cu. An example of the oxide superconductor composition is a superconductor having an REBa_{y} Cu₃O_{z}-based (where RE is at least one element selected from Y, Nd, Sm, Eu, Dy, Gd and Ho, and y<2 and z=6.2 to 7) composition. When RE is Y, the composition control of the superconductor can be easily performed.

The RE component of the oxide superconductor composition according to the present embodiment is composed of at least one of RE salts of C₃₋₈ carboxylic acids free from a ketone group. Here, desirably, the RE salt is an RE salt of propionic acid, and is an yttrium propionate in which fluorine atom is not contained in the yttrium salt.

When propionic acid that produces an RE salt and has less than 3 carbon atoms is used, sufficient solubility cannot be obtained, and uniform oxide superconductor thick film cannot be obtained. In addition, when propionic acid having greater than 8 carbon atoms is used, since the amount of CO₂ gas generated during pre-baking treatment increases, the coating film easily scatters, and consequently it is difficult to achieve a highly functional oxide superconductor thick film.

The Ba component of the oxide superconductor composition according to the present embodiment is a barium trifluoroacetate represented by (CF₃COO) 2Ba.nH₂O (where n is 0 or possible hydration numbers), and normally is obtained as anhydride or monohydrate. The use of a trifluoroacetate as a precursor compound of an oxide superconductor is conventionally known, and has an advantage that barium carbonate whose conversion temperature to an oxide superconductor is high is not entailed. Such an advantage is most efficiently obtained when the Ba component is a trifluoroacetate. When a trifluoroacetate is used for the RE component, not for the Ba component, the effect of the present invention cannot be obtained, and when a trifluoroacetate is used for the Cu component, the effect of improving solubility described later cannot be obtained.

The Cu component contained in the oxide superconductor composition according to the present embodiment is at least one that is selected from the group consisting of copper salts of C₆₋₁₆ branched saturated aliphatic carboxylic acids and copper salts of C₆₋₁₆ alicyclic carboxylic acids. The copper salt is represented by L²₂Cu.pH₂O (where L² is C₆₋₁₆ branched saturated aliphatic carboxylic acid residue or C₆₋₁₆ alicyclic carboxylic residue, and p is 0 or possible hydration numbers), and normally is obtained as anhydride or mono- or di-hydrate. Examples of the C₆₋₁₆ branched saturated aliphatic carboxylic acid that produces the copper salt include 2-ethylhexanoic acid, isononanoic acid, neodecanoic acid and the like. Examples of the C₆₋₁₆ alicyclic carboxylic acid that produces the copper salt include cyclohexane carboxylic acid, methylcyclohexane carboxylic acid, and naphthenic acid. While, in the above-mentioned carboxylic acids, the carboxylic acids derived from natural products such as naphthenic acid may not satisfy the number of carbon atoms defined in the present invention or may contain a component having no branch or alicyclic group, commercially available products may be normally used as they are in the present invention regardless of presence/absence of the component.

Here, the oxide superconductor composition contains Ba-TFA, Cu-2-ethylhexanoic acid and Y-propionic acid as an RE salt of a C₃₋₈ carboxylic acid free from a ketone group.

Preferably, the above-mentioned copper salt is a copper salt of synthetic carboxylic acids such as copper neodecanoate, copper 2-ethylhexanoate, and copper isononanoate in view of stable performance and quality. In addition, advantageously, copper neodecanoate, copper 2-ethylhexanoate, copper isononanoate, and copper naphthenate themselves have favorable solubility in organic solvent, and further have an effect of improving solubility of the barium salt and the RE salt according to the embodiment of the present invention.

Preferably, in the oxide superconductor composition according to the present embodiment, the total content of the RE component, the Ba component and the Cu component is 10 to 60 wt %, more preferably 30 to 50 wt %, and in molar concentration (the sum of three components), 0.5 to 2.0 mol/L, more preferably 0.7 to 1.5 mol/L.

In addition, the oxide superconductor composition of the embodiment of the present invention contains the above-mentioned RE component, Ba component and Cu component such that the molar ratio of Ba falls within a range of a<2 when the molar ratio of RE, Ba and Cu is expressed as Y:Ba:Cu=1:a:3. In this case, for the purpose of obtaining high critical current density Jc and critical current value Ic, the molar ratio of Ba in the material solution preferably falls within a range of 1.0<a<1.8, more preferably, a range of 1.3<a<1.7.

Segregation of Ba can be limited in this manner, and as a result, deposition of Ba-based impurities in the grain boundary is limited. Thus, the possibility of crack is limited and electrical binding among crystal grains is improved. Consequently, it is possible to readily produce an oxide superconductive wire having a uniform and thick tape-shaped oxide superconductor having excellent superconductive characteristics by forming a superconductor film by using an MOD method.

In addition, the organic solvent in the oxide superconductor composition according to the present embodiment is not limited as long as it dissolves at least the RE component, among the RE component, the Ba component and the Cu component. To be more specific, the organic solvent may be arbitrarily selected to ensure a desired application performance, solubility, viscosity, dissolution stability and the like, and a combination of two or more kinds of organic solvents may also be adopted.

Examples of the organic solvent include alcoholic solvents, diol solvents, ester solvents, ether solvents, aliphatic or alicyclic hydrocarbon solvents, aromatic hydrocarbon solvents, hydrocarbon solvents having a cyano group, halogenated aromatic hydrocarbon solvents, and other solvents.

Examples of the alcoholic solvents include methanol, ethanol, propanol, isopropanol, 1-butanol, isobutanol, 2-butanol, tert-butanol, pentanol, isopentanol, 2-pentanol, neopentanol, tert-pentanol, hexanol, 2-hexanol, heptanol, 2-heptanol, octanol, 2-ethyl hexanol, 2-octanol, cyclopentanol, cyclohexanol, cycloheptanol, methylcyclopentanol, methylcyclohexanol, methylcycloheptanol, benzil alcohol, ethylene glycol monomethyl ether, ethylene glycol monoethyl ether, propylene glycol monomethyl ether, propylene glycol monoethyl ether, diethylene glycol monomethyl ether, diethylene glycol monoethyl ether, triethylene glycol monomethyl ether, triethylene glycol monoethyl ether, 2-(N, N-dimethyl amino) ethanol, and 3 (N, N-dimethylamino) propanol.

Examples of the diol solvents include ethylene glycol, propylene glycol, 1,2-butanediol, 1,3-butanediol, 1,4-butanediol, 1,5-pentanediol, neopentyl glycol, isoprene glycol (3-methyl-1,3-butanediol), 1,2-hexanediol, 1,6-hexanediol, 3-methyl-1,5-pentanediol, 1,2-octanediol, octanediol (2-ethyl-1,3-hexanediol), 2-butyl-2-ethyl-1,3-propane diol, 2,5-dimethyl-2,5-hexanediol, 1,2-cyclohexanediol, 1,4-cyclohexanediol, and 1,4-cyclohexane dimethanol.

Examples of the ketone solvents include acetone, ethyl methyl ketone, methyl isopropyl ketone, methyl butyl ketone, methyl isobutyl ketone, methyl amyl ketone, methyl hexyl ketone, ethylbutyl ketone, diethyl ketone, dipropyl ketone, diisobutyl ketone, methyl amyl ketone, cyclohexanone, and methylcyclohexanone.

Examples of the ester solvents include methyl formate, ethyl formate, methyl acetate, ethyl acetate, isopropyl acetate, butyl acetate, isobutyl acetate, secondary-butyl acetate, tert-butyl acetate, amyl acetate, isoamyl acetate, tert-amyl acetate, phenyl acetate, methyl propionate, ethyl propionate, isopropyl propionate, butyl propionate, isobutyl propionate, secondary-butyl propionate, tert-butyl propionate, amyl propionate, isoamyl propionate, tert-amyl propionate, phenyl propionate, 2-methyl ethylhexanoate, 2-ethyl ethylhexanoate, 2-propyl ethylhexanoate, 2-isopropyl ethylhexanoate, 2-butyl ethylhexanoate, methyl lactate, ethyl lactate, methylmethoxy propionate, methylethoxy propionate, ethylmethoxy propionate, ethylethoxy propionate, ethylene glycol monomethylether acetate, diethylene glycol monomethylether acetate, ethylene glycol monoethylether acetate, ethylene glycol monopropylether acetate, ethylene glycol monoisopropyl ether acetate, ethylene glycol monobutylether acetate, ethylene glycol monosecondary-butyl ether acetate, ethylene glycol monoisobutylether acetate, ethylene glycol mono-tert-butylether acetate, propylene glycol monomethylether acetate, propylene glycol monoethylether acetate, propylene glycol monopropylether acetate, propylene glycol monoisopropylether acetate, propylene glycol monobutylether acetate, propylene glycol monosecondary-butylether acetate, propylene glycol monoisobutylether acetate, propylene glycol mono-tert-butylether acetate, butylene glycol monomethylether acetate, butylene glycol monoethylether acetate, butylene glycol monopropylether acetate, butylene glycol monoisopropylether acetate, butylene glycol monobutylether acetate, butylene glycol monosecondary-butylether acetate, butylene glycol monoisobutylether acetate, butylene glycol mono-tert-butylether acetate, methyl acetoacetate, ethyl acetoacetate, methyl oxobutanoate, ethyl oxobutanoate, γ-lactone, dimethyl malonate, dimethyl succinate, propylene glycol diacetate, and δ-lactone.

Examples of the ether solvents include tetrahydrofuran, tetrahydropyran, morpholine, ethylene glycol dimethyl ether, diethylene glycol dimethyl ether, dipropylene glycol dimethyl ether, triethylene glycol dimethyl ether, dibutyl ether, diethyl ether, and dioxane.

Examples of the aliphatic or alicyclic hydrocarbon solvents include pentane, hexane, cyclohexane, methylcyclohexane, dimethylcyclohexane, ethylcyclohexane, heptane, octane, decalin, solvent naphtha, turpentine oils, D-limonene, pinene, mineral spirit, SWASOL #310 (COSMO MATSUYAMA OIL CO., LTD Inc.), and SOLVESSO #100 (Exxon Chemical Inc.).

Examples of the aromatic hydrocarbon solvents include benzene, toluene, ethylbenzene, xylene, mesitylene, diethylbenzene, cumene, isobutyl benzene, cymene, and tetralin.

Examples of the hydrocarbon solvents having a cyano group include acetonitrile, 1-cyanopropane, 1-cyanobutane, 1-cyanohexane, cyanocyclohexane, cyanobenzene, 1,3-dicyanopropane, 1,4-dicyanobutane, 1,6-dicyanohexane, 1,4-dicyanocyclohexane, and 1,4-dicyanobenzene.

Examples of the halogenated aromatic hydrocarbon solvents include carbon tetrachloride, chloroform, trichloro ethylene, and methylene chloride.

Examples of the other organic solvents include N-methyl-2-pyrrolidone, dimethylsulfoxide, dimethylformamide, aniline, triethylamine, and pyridine.

Preferably, the above-mentioned organic solvents have a boiling point of 80° C. or above since uniform application can be achieved with such organic solvents. In addition, alcoholic solvents are preferable since alcoholic solvents have favorable wettability to various base materials. In particular, it is preferable to use C₄₋₈ alcoholic solvents such as 1-butanol, isobutanol, 2-butanol, tert-butanol, pentanol, isopentanol, 2-pentanol, neopentanol, tert-pentanol, hexanol, 2-hexanol, heptanol, 2-heptanol, octanol, 2-ethyl hexanol, 2-octanol, ethylene glycol monoethylether, propylene glycol monomethylether, propylene glycol monoethylether, and diethylene glycol monomethylether.

The content of the organic solvent in the oxide superconductor composition is 25 to 80 wt %. The content of the organic solvent in the oxide superconductor composition is preferably 40 to 70 wt % when the application property, the concentration of metal component, and the stability of dissolution are taken into consideration.

The oxide superconductor composition of an embodiment of the present invention further contains in the organic solvent an amino group-containing solubilizer for dissolving propionate. Examples of the amino group include tetra methyl urea, n-octyl amine, propyl amine and the like. In particular, tetra methyl urea is preferable since tetramethyl urea is a high-melting point solvent.

In addition, the organic solution may contain optional components including leveling agents, thickeners, stabilizers, surfactants, dispersants and the like. It is to be noted that the content of these optional components in the oxide superconductor composition of the embodiment of the present invention is preferably 10 wt % or lower. Specific examples of the above-mentioned optional components include organic acids that function as a leveling agent. As the organic acids, C₆₋₃₀ organic acids are favorable, which may have a hydroxyl group, a branch, and an unsaturated bond. Specific examples of the organic acids include 2-ethylhexane acid, isononanoic acid, neodecanoic acid, undecanoic acid, lauric acid, tridecanoic acid, myristic acid, pentadecanoic acid, palmitic acid, margaric acid, stearic acid, nonadecanoic acid, arachidic acid, behenic acid, lignoceric acid, cerotic acid, montanoic acid, melissic acid, obtusilic acid, linderic acid, tsuzuic acid, palmitoleic acid, petroselinic acid, oleic acid, elaidic acid, vaccenic acid, linoleic acid, linoelaidic acid, γ-linolenic acid, linolenic acid, ricinoleic acid, 12-hydroxy stearic acid, cyclohexane carboxylic acid, methylcyclohexane carboxylic acid, naphthenic acid, rosin acid, and abietic acid, with abietic acid being preferable.

It is to be noted that the viscosity of the oxide superconductor composition of an embodiment of the present invention preferably falls within a range of 2 to 150 [mPa·s], and in this case, the viscosity is 20 [mPa·s].

### <Outline of MOD Method Using Oxide Superconductor Composition of Present Embodiment>

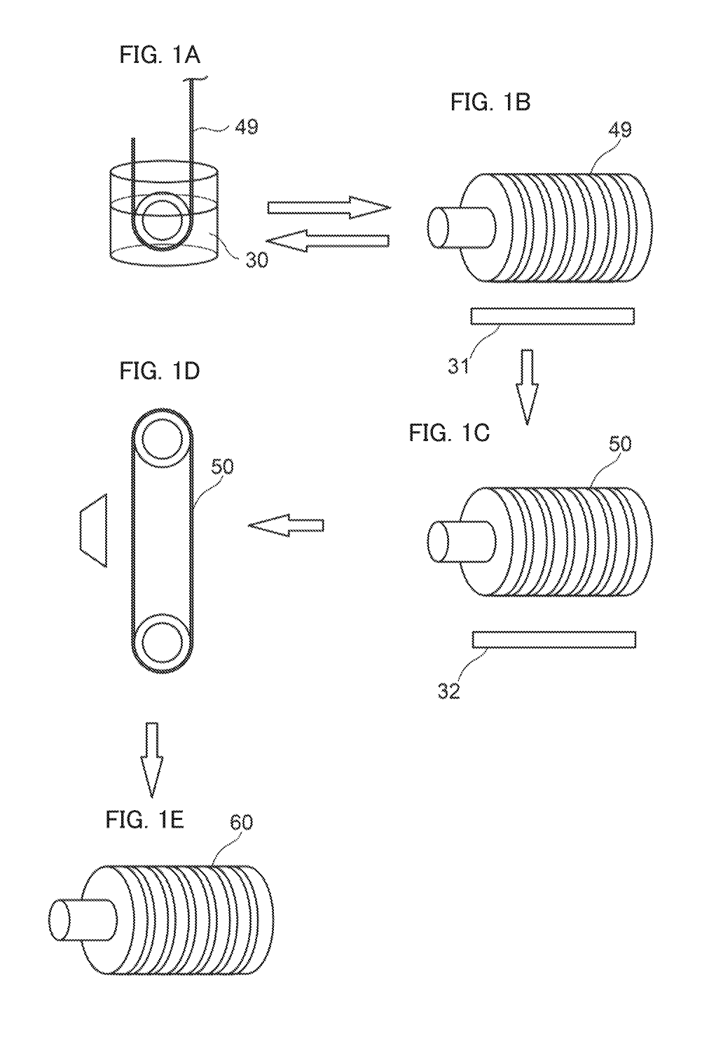

FIGS. 1A to 1E are schematic views illustrating a manufacturing method of a tape-shaped oxide superconductive wire (hereinafter referred to also as “YBCO superconductive wire”) having an REBaCuO (where RE is at least one element selected from the group consisting of Y, Nd, Sm, Gd, Dy, Eu, Er, Yb, Pr and Ho)-based superconductive layer with use of an MOD method.

First, a Gd₂Zr₂O₇-intermediate layer and a Y₂O₃-intermediate layer are sequentially formed as a template on a tape-shaped Ni-alloy substrate by an ion beam sputtering method, and on the layers thus formed, an MgO-intermediate layer is formed by an IBAD method. Thereafter, a LaMnO₃-intermediate layer is formed by a sputtering method, and then a CeO₂-intermediate layer is formed by PLD method or a sputtering method to form a base material serving as a composite substrate.

Then, in an application step (see FIG. 1A), the oxide superconductor composition according to the present embodiment, that is, mixture solution (superconductive material solution) 30 obtained by dissolving a Y-propionate, a Ba-TFA salt (trifluoroacetate) and a Cu-ethyl hexane salt in organic solvent at a ratio of Y:Ba:Cu=1:1.5:3 is applied on the base material by a dip-coating method.

In the dip-coating method, a tape-shaped base material in which an oxide intermediate layer is formed on the substrate is dipped (immersed) in a container storing mixture solution 30, and then the tape-shaped base material is lifted from mixture solution 30 to thereby apply the mixture solution on the surface of the base material. In the dip-coating method, mixture solution 30 is applied, that is, a coating film is formed such that the film thickness is adjusted by the surface tension of the mixture solution at the time of the lifting. The dip-coating method can control the film thickness by the lifting speed of the base material and the solution concentration. As the lifting speed is reduced, the thickness of the film applied on the base material at the time of lifting is reduced, and as the lifting speed is increased, the film thickness is increased. Here, desirably, the moving speed of the base material in the dip-coating method is set to 5 to 30 [m/h].

After mixture solution 30 is applied to the base material in the above-mentioned manner, the base material (wire 49) on which mixture solution 30 is applied is subjected to pre-baking in a pre-baking treatment step (see FIG. 1B). In the pre-baking treatment step (see FIG. 1B), for example, wire 49 on which mixture solution 30 (see FIG. 1A) is applied is spirally wound on a peripheral surface of a cylinder. The cylinder on which wire 49 is wound in this manner is heated with heater 31 or the like for a predetermined time in an atmosphere of a predetermined water vapor partial pressure and an oxygen partial pressure while being rotated in a baking apparatus. The application step (see FIG. 1A) and the pre-baking treatment step (see FIG. 1B) are repeated predetermined times, and a film body as a superconductive precursor having a desired film thickness is formed on the intermediate layer of base material 49. It is to be noted that, in FIG. 1A, reference numeral 49 indicates a wire in a state where a film body as a superconductive precursor is formed on the base material (the base material on which mixture solution 30 is not yet applied, and the base material on which a coating film is formed after the pre-baking treatment). Preferably, in the pre-baking treatment step (see FIG. 1B), wire 49 is subjected to the pre-baking treatment in the baking apparatus in an atmosphere of a water vapor partial pressure of 3 to 76 Torr and an oxygen partial pressure of 300 to 760 Torr and in a temperature range of 400 to 500° C., for example. In addition, the temperature rise rate in the pre-baking treatment may be equal to or greater than 30 [° C./min]. Preferably, the pre-baking treatment is performed for 1 to 10 hours, more preferably, 2 to 7 hours.

Thereafter, in a main baking treatment step (see FIG. 1C), tape-shaped wire 50 in which a film body as a superconductive precursor is formed on the intermediate layer of the base material is subjected to crystallization thermal treatment of the film body of the superconductive precursor, that is, a thermal treatment for producing a YBCO superconductor. It is to be noted that, in the main baking treatment step (see FIG. 1C), for example, wire 50 is spirally wound on the peripheral surface of the cylinder, and the cylinder is heated with heater 32 or the like for a predetermined time in an atmosphere of a predetermined water vapor partial pressure and an oxygen partial pressure while being rotated in the baking apparatus. Preferably, in the main baking treatment step (see FIG. 1C), the main baking treatment is performed in the baking apparatus, in an atmosphere of a water vapor partial pressure of 30 to 600 Torr and an oxygen partial pressure of 0.05 to 1 Torr and in a temperature range of 700 to 800° C. Preferably, the main baking treatment is performed for 5 to 30 hours, more preferably, 10 to 15 hours while introducing water vapor gas. In the main baking treatment, the precursor is heated at a temperature rise rate of 30[° C./min].

Next, after a Ag stabilization layer is applied on the YBCO superconductor of wire 50 by a sputtering method in a stabilization layer forming step (see FIG. 1D), a post-thermal treatment is performed in a post-processing step (see FIG. 1E) to produce tape-shaped YBCO superconductive wire (oxide superconductive wire) 60.

Here, the application step (see FIG. 1A) and the pre-baking treatment step (see FIG. 1B) are repeated one to ten times.

In the application step (see FIG. 1A), the REBaCu (where RE is at least one element selected from the group consisting of Y, Nd, Sm, Gd, Dy, Eu, Er, Yb, Pr and Ho)-based oxide superconductor composition according to the present embodiment is applied as a mixture solution on the base material (indicated as wire 49 in the drawings). The oxide superconductor composition contains as an essential component an RE salt of a C₃₋₈ carboxylic acid free from ketone group as an RE component.

Thus, in the application step (see FIG. 1A), when a mixture solution is applied to the base material by the dip-coating method, wettability can be improved in comparison with a case where a mixture solution containing an RE salt containing a ketone group is applied. For example, the RE component in the mixture solution that is the oxide superconductor composition according to the present embodiment is a propionate (hereinafter referred to as “propionic liquid”). When mixture solution 30 containing the propionic liquid is used, it is not easily dried in comparison with a conventional mixture solution containing 2-ethyl hexane salt as a mixture solution containing a ketone group (hereinafter referred to as “ethyl hexane liquid”) is used. In other words, when dip coating is performed with the ethyl hexane liquid as the RE component, evaporation (drying) easily occurs in comparison with a case where dip coating is performed with the propionic liquid (oxide superconductor composition) of the present embodiment.

For this reason, when the base material is lifted after mixture solution containing ethyl hexane liquid is applied, the coating film on the base material is dried in a shape bulging at both ends as viewed in the axial direction due to factors such as the surface tension and polarity of the mixture solution.

In contrast, in the present embodiment in which dip coating is performed with propionic liquid, since solubilizer having an amino group is contained, evaporation (scattering) is not easily occur. Therefore, when the coating film on the base material on which propionic liquid is applied is lifted, the coating film is dried in a state where the coating film is applied as a film body which is uniform at both end portions and a center portion as viewed in the axial direction.

As a result, in the dip coating with the propionic liquid of the present embodiment, the thickness of the film per application is increased in comparison with the dip coating using the ethyl hexane liquid. For example, when dip coating was performed using the ethyl hexane liquid with a solution concentration and a lifting speed which are optimized such that the thickness of the film per application is maximized, the thickness of the coating film per application (coating film thickness) was 0.11 [μm/coat]. In contrast, when dip coating was performed using the propionic liquid (mixture solution 30) of the present embodiment with a solution concentration and a lifting speed which are optimized such that the thickness of the film per application is maximized, the thickness of the film per application was 0.3 [μm/coat] or greater. Thus, in comparison with the dip coating with the ethyl hexane liquid, a coating film that serves as a superconductive precursor can be formed into a thick film.

In addition, mixture solution 30 as an oxide superconductor composition that contains, as the essential component, propionic acid (C₃H₆O₂) salt as the RE component can reduce the amount of C in comparison with the case where levulinic acid (C₅H₈O₃) is used. Thus, while limiting generation of carbon dioxide and reducing occurrence of crack, the thickness of the oxide superconductor can be increased.

It is to be noted that the Ni-alloy substrate may be a biaxially oriented substrate, or a non-oriented substrate on which a biaxially oriented intermediate layer film is formed. In addition, at least one intermediate layer is formed. The application method may be an ink-jet method, a spraying method and the like as well as the above-mentioned dip-coating method, and basically, any process may be adopted as long as the mixture solution can be continuously applied on a composite substrate. The thickness of the film per application is 0.01 μm to 2.0 μm, more preferably 0.1 μm to 1.0 μm.

The oxide superconductor formed in the above-mentioned manner is applicable to a wire, a device, power apparatuses such as a power cable, a transformer and a current limiter, and the like.

### EXAMPLES

The present invention will be described below with reference to Examples, but the present invention is not limited to Examples.

### Example 1

In Example 1, with use of the oxide superconductor composition of the present embodiment, an REBaCu-based oxide superconductor (YBCO superconductor) was formed on a tape-shaped base material by an MOD method illustrated in FIGS. 1A to 1E. The base material of Example 1 includes HASTELLOY (registered trademark) as a substrate, and an intermediate layer obtained by sequentially stacking GZO, MgO, LMO, and CeO₂ on the HASTELLOY (registered trademark). Mixture solution 30 (see FIGS. 1A to 1E) used in the dip-coating method contains Ba-TFA, Cu-2-ethylhexanoic acid, and Y-propionic acid free from fluorine atom, and organic solvent for dissolving the components of Y-propionic acid, Ba-TFA, and Cu-2-ethylhexanoic acid. Additionally, the organic solvent contains an amino group-containing solubilizer (here, tetra methyl urea) for dissolving propionic acid. In the dip-coating method, the critical film thickness of the superconductor per application is 1.2 [μm/coat] (application rate: 5 [m/h]), and the thickness of the coating film per application was 0.49 [μm/coat]. Such application was repeated multiple times until a desired film thickness (here, a film thickness greater than 2.5 [μm]) was obtained.

### Example 2

An YBCO superconductor is formed by the MOD method in the same manner as in Example 1 except that, in the application step, the application rate was doubled, that is, 10 [m/h], and the base material was dip-coated with mixture solution 30 (see FIGS. 1A to 1E) to form an YBCO superconductor. In Example 2, the thickness of the coating film per application was 0.77 [μm/coat]. Such application was repeated multiple times until a desired film thickness (here, a film thickness greater than 2.0 [μm]) was obtained.

### Example 3

A mixture solution similar to the mixture solution used in Example 1 in which organic solution is free from the solubilizer having an amino group was applied on the base material same as that of Example 1 by the dip-coating method, and a film thus obtained was subjected to pre-baking treatment and main baking treatment to form an oxide superconductive wire. The application rate was 5 [m/h], and the conditions of the application, the pre-baking treatment and the main baking treatment were the same as those of Examples.

### Reference Example 1

As Reference Example, a mixture solution containing Y-TFA, Ba-TFA, and Cu-2-ethylhexanoic acid as TFA-MOD material solution was used to form a YBCO superconductor on a tape-shaped base material by the MOD method in the same manner as that of Example 1. The application rate was 5 [m/h], and the thickness of the coating film per application was 0.11 (approximately 0.1) [μm/coat], and the application step and the pre-baking step were repeated to obtain a desired film thickness (here, a film thickness of 2 [μm] was obtained by repeating the steps 20 times). The conditions of the application, the pre-baking treatment and the main baking treatment were the same as those of Examples.

Results of the measurement are shown in Table 1.

TABLE 1

| | | Number of | | |
|---|---|---|---|---|
| | | applications | Film thickness | |
| | | required | of YBCO | |
| | | superconductor | [Film thickness | Superconductive |
| | Application | for desired film | obtained by one | characteristic Ic |
| | rate | thickness | coating] | (Jc) |
| Ex.1 | 5 [m/h] | 6 | 2.91 μm | 791A/cm-w |
| | | | [0.49 μm/coat] | |
| Ex.2 | 10 [m/h] | 3 | 2.30 [μm] | 405A/cm-w |
| | | | [0.77 μm/coat] | |
| Ref | 5 [m/h] | 20 | 2.0 μm | 400A/cm-w |
| Ex.1 | | | [0.11 μm/coat] | |
| Ex.3 | 5 [m/h] | 5 | 2.0 μm | 400A/cm-w |
| | | | [0.45 μm/coat] | |

With reference to Table 1, the film thickness of mixture solution applied on the base material by one dip coating in Examples 1 to 3 is greater than that of Reference Example 1. The film thickness obtained by one coating in Example 1 and Example 2 were approximately four times greater and approximately seven times greater than that of Reference Example 1, respectively. The film thickness obtained by one coating in Example 3 was approximately four times greater than that of Reference Example 1.

In Example 1, at the time of stacking the coating film, the application step and the pre-baking treatment step were repeated six times to obtain a desired film thickness of the YBCO superconductor of the oxide superconductive wire. In Reference Example 1, the application step and the pre-baking treatment step in the MOD method have to be repeated 29 times to obtain the film thickness obtained in Example 1. It was found from this result that Example 1 can achieve increase in film thickness and speed and reduction in manufacturing cost at the time of forming the oxide superconductive wire having an oxide superconductor in comparison with Reference Example 1. In addition, in Example 1, excellent characteristics were achieved with critical current value Ic of 791 [A/cm-w] and the critical current density Jc of 2.7 [MA/cm²]. It is to be noted that critical current value Ic and critical current density Jc (voltage criteria 1 μV/cm) that represent the superconductive characteristic were measured by a direct current four-terminal method.

Further, when the application rate of mixture solution 30 (see FIGS. 1A to 1E) in the dip-coating method of Example 1 is increased from 5 [m/h] to 10 [m/h] as in Example 2, the number of the application step and the pre-baking treatment step can be reduced. In this manner, Example 2 can further achieve increase in film thickness and speed and reduction in manufacturing cost at the time of forming the oxide superconductive wire having an oxide superconductor in comparison with Example 1.

While the embodiment of the present invention has been described hereinabove, the above-mentioned description is merely a preferred example of the present invention, and the scope of the present invention is not limited thereto. That is, the above-mentioned configurations of the apparatus and the shapes of the components are merely examples, and the present invention may be further modified within the scope and spirit of the invention.

The disclosure of the specification, drawings, and abstract in Japanese Patent Application No. 2013-039810 filed on Feb. 28, 2013 is incorporated herein by reference in its entirety.

### INDUSTRIAL APPLICABILITY

The oxide superconductor composition, the oxide superconductive wire and the manufacturing method of the oxide superconductive wire according to the embodiment of the present invention can achieve increase in film thickness and speed and reduction in manufacturing cost, and are suitable for production of an oxide superconductive wire by an MOD method.

### REFERENCE SIGNS LIST

30: Mixture solution
49, 50: Wire
60: YBCO superconductive wire

1. An oxide superconductor composition for forming an REBaCuO (where RE is at least one element selected from the group consisting of Y, Nd, Sm, Gd, Dy, Eu, Er, Yb, Pr and Ho)-based oxide superconductor, the oxide superconductor composition comprising, as essential components:
an RE salt of a C₃₋₈arboxylic acid that is free from a ketone group and serves as an RE component;
barium trifluoroacetate that serves as a Ba component;
at least one copper salt that serves as a Cu component selected from the group consisting of copper salts of C₆₋₁₆ branched saturated aliphatic carboxylic acids and copper salts of C₆₋₁₆ alicyclic carboxylic acids; and
an organic solvent that dissolves salts of the metals.

2. The oxide superconductor composition according to claim 1, wherein the RE component is composed of an yttrium salt.

3. The oxide superconductor composition according to claim 1, wherein the RE component is composed of a propionate free from fluorine atom.

4. The oxide superconductor composition according to claim 1, wherein the organic solvent contains a solubilizer having an amino group.

5. An oxide superconductive wire comprising an REBaCuO (where RE is at least one element selected from the group consisting of Y, Nd, Sm, Gd, Dy, Eu, Er, Yb, Pr and Ho)-based oxide superconductor, the oxide superconductor including, as essential components:
an RE salt of a Cₘ carboxylic acid that is free from ketone group and serves as an RE component;
barium trifluoroacetate that serves as a Ba component;
at least one copper salt that serves as a Cu component selected from the group consisting of copper salts of C₆₋₁₆ branched saturated aliphatic carboxylic acids and copper salts of C₆₋₁₆ alicyclic carboxylic acids; and
an organic solvent that dissolves salts of the metals.

6. The oxide superconductive wire according to claim 5, wherein the RE component is composed of an yttrium salt.

7. The oxide superconductive wire according to claim 5, wherein the RE component is composed of a propionate free from fluorine atom.

8. A manufacturing method of an oxide superconductive wire, the method comprising:
applying a solution of the oxide superconductor composition according to claim 1 to a surface of a tape-shaped base material by lifting the base material from a container storing the solution;
applying pre-baking treatment to the solution applied on the base material to form a precursor of an oxide superconductor on the surface of the base material; and
forming an REBaCuO (where RE is at least one element selected from the group consisting of Y, Nd, Sm, Gd, Dy, Eu, Er, Yb, Pr and Ho)-based oxide superconductor on the surface of the base material by applying main baking treatment to the precursor to cause crystallization.

9. The method according to claim 8, wherein the application of the solution of the oxide superconductor composition and the application of the pre-baking treatment are repeated one to ten times to form the precursor.
